(19) United States
(12) Patent Application Publication
(10) Pub. No.: US 2026/0331201 A1
(43) Pub. Date: Oct. 22, 2026

(54) MEMORY ARRAY NOISE EMULATION CIRCUITRY

(71) Applicant: Micron Technology, Inc., Boise, ID (US)

(72) Inventors: Sujeet Ayyapureddi, Boise, ID (US); David R. Brown, Allen, TX (US); Gary L. Howe, Allen, TX (US)

(21) Appl. No.: 19/554,403

(22) Filed: Mar. 2, 2026

Related U.S. Application Data
(60) Provisional application No. 63/792,200, filed on Apr. 21, 2025.

(51) Int. Cl. G11C 29/12

(52) U.S. Cl. CPC G11C 29/12015; G11C 29/12005; G11C 29/1201

(57) ABSTRACT

Systems and methods include a processor that acquires a current profile at one or more pads of a memory device and performs frequency analysis on the current profile to determine frequency components of array noise at the one or more pads. The processor also determines contributions of frequency components above a threshold and sends instructions to generate signals based on each of the frequency components above the threshold. The system also includes a test chip coupled to the processor and includes clock generation circuitry configured to receive the instructions and to generate the signals based on the instructions. The test chip also includes noise generation circuitry configured to switch a plurality of transistors to short voltage rails together to generate emulated noise to mimic memory array noise of the memory device.

### CROSS-REFERENCE TO RELATED APPLICATION

This application claims priority to U.S. Provisional Application No. 63/792,200, filed Apr. 21, 2025, which is incorporated by reference herein in its entirety.

### BACKGROUND

### Field of the Invention

Embodiments of the present disclosure relate generally to the field of semiconductor memory devices. More specifically, embodiments of the present disclosure relate to noise emulation circuitry configured to emulate noise.

### Description of the Related Art

The operational rate of memory devices, including the data rate of a memory device, has been increasing over time. As a side effect of the increase in speed of a memory device, data errors may become more problematic. For example, memory devices may be susceptible to voltage and/or temperature variations that may negatively impact signal integrity and/or data reliability especially in high-speed memory systems. To test such conditions, test input-output (IO) chips may be used to emulate behaviors of a memory device without incorporating a memory array and associated bank logic.

### BRIEF DESCRIPTION OF THE DRAWINGS

Various aspects of this disclosure may better be understood upon reading the following detailed description and upon reference to the drawings in which:

FIG. 1 is a simplified block diagram illustrating certain features of a memory device that includes a memory array and noise filtration circuitry configured to at least partially filter noise from the memory array, according to an embodiment of the present disclosure;

FIG. 2 illustrates a block diagram of a test chip that includes test circuitry to be tested, pads, and noise generation circuitry to emulate memory array noise from the memory device of FIG. 1, according to an embodiment of the present disclosure;

FIG. 3 illustrates a circuit diagram of the noise generation circuitry of FIG. 2 using control signals, according to an embodiment of the present disclosure;

FIG. 4 illustrates a timing diagram of the control signals of FIG. 3, according to an embodiment of the present disclosure; and

FIG. 5 is a flow diagram illustrating a process for designing and driving the noise generation circuitry of FIG. 3 in the test chip of FIG. 2, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As may be appreciated, dynamic random-access memory (DRAM) devices may have multiple noise events. For instance, the noise events may include sense amplifiers of a memory array turning on, write drivers writing data into the sense amplifiers, and/or other switching events that may create noise in the memory device. When a test chip is deployed to test IO, the memory array and associated bank logic may be omitted from the test chips. However, these test chips may not properly emulate behavior of the memory device since the noise generated by the memory array may be missing. To address such lack of noise in the test chip, the test chip may include one or more noise generation circuitries that emulate the periodic noise of the memory arrays by switching transistors to short power rails, such as VCC and VSS, together to generate a noise profile on the power rails. The amount of magnitude in noise on the power rails may depend on the width of the transistor. When the dips on the different power rails have a phase difference, the noise generation circuitry may emulate the phase generation by using a capacitor between the rails and charging and discharging the capacitor with the phase difference between control signals.

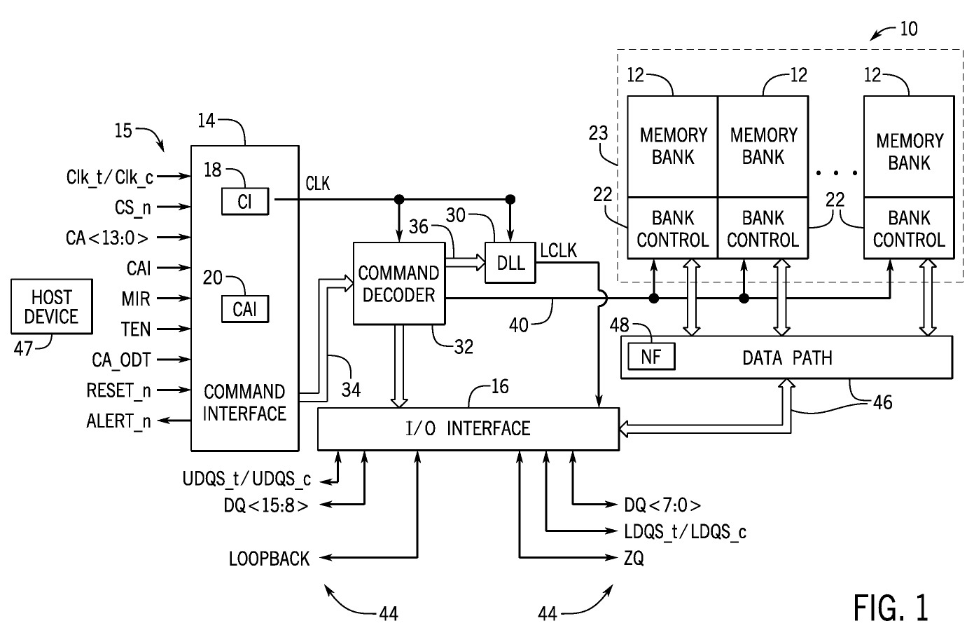

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type four (DDR4 SDRAM), a double data rate type five synchronous dynamic random-access memory (DDR5 SDRAM) device, a low-power double data rate type four (LPDDR4 SDRAM), a low-power double data rate type five (LPDDR5 SDRAM), and/or another new type, such as double data rate type six (DDR6 SDRAM). Various features of DDR SDRAM devices allow for reduced power consumption, more bandwidth and more storage capacity compared to prior generations of DDR SDRAM. Furthermore, in some implementations, the memory device 10 may be other types of DRAM, such as High Bandwidth Memory (HBM).

The memory device 10 may include a number of memory banks 12. The memory banks 12 may be DDR6 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 GB DDR5 SDRAM, the memory chip may include 32 memory banks 12, arranged into 8 bank groups, each bank group including 4 memory banks, for instance. Various other configurations, organization, and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from host device 47, such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the complementary clock signal (Clk_c). The positive clock edge for DDR refers to the point where the rising true clock signal Clk_t crosses the falling complementary clock signal Clk_c, while the negative clock edge indicates that transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal CLK. The internal clock signal CLK is supplied to an internal clock generator 30, such as a delay locked loop (DLL) circuit. The internal clock generator 30 generates a phase controlled internal clock signal LCLK based on the received internal clock signal CLK. The phase controlled internal clock signal LCLK is supplied to the I/O interface 16, for instance, and is used as a timing signal for determining an output timing of read data.

The internal clock signal CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the internal clock generator 30 over the bus 36 to coordinate generation of the phase controlled internal clock signal LCLK. The phase controlled internal clock signal LCLK may be used to clock data through the I/O interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other features, such as timing control and data control, to facilitate the execution of commands to and from the memory banks 12. Collectively, the memory banks 12 and the bank control blocks 22 may be referred to as a memory array 23.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over a databus 46 that includes multiple bi-directional data connections. Data I/O signals, generally referred to as DQ signals, are generally transmitted and received in one or more bi-directional data connections. For certain memory devices, such as a DDR5 SDRAM memory device, the I/O signals may be divided into upper and lower bytes. For instance, for an x16 memory device, the I/O signals may be divided into upper and lower I/O signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance. In some embodiments as discussed below, the DQS may be internally generated from a clock received at the memory device 10 from the host device 47. In some such embodiments the DQS pins may be omitted from the memory device 10.

An impedance (ZQ) calibration signal may also be provided to the memory device 10 through the I/O interface 16. The ZQ calibration signal may be provided to a reference pin and used to tune output drivers and ODT values by adjusting pull-up and pull-down resistances of the memory device 10 across changes in process, voltage, and temperature (PVT) values. Because PVT characteristics may impact the ZQ resistor values, the ZQ calibration signal may be provided to the ZQ reference pin to be used to adjust the resistance to calibrate the input and output impedances to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the I/O interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory system 10. Accordingly, it should be understood that the block diagram of FIG. 1 is only provided to highlight certain functional features of the memory device 10 to aid in the subsequent detailed description.

In some embodiments, the memory device 10 may be coupled to a host device 47. The host device 47 may include a processor, such as a central processing unit (CPU), a graphics processing unit (GPU), another microprocessor, a programmable logic device, and/or any other suitable processor that controls processing of system functions and requests. Further, any host device/processor may include multiple processing units.

As previously mentioned, the memory array (e.g., the memory banks 12) and/or their bank controls 22 may generate noise during operation of the memory device 10. For instance, the memory array may generate noise when switching on sensing amplifiers, write drivers writing data into the sensing amplifiers, and/or other periodic events. Such noise may propagate through the memory device 10. The memory device 10 may include noise filtration circuitry (NF) 48 to attempt to attenuate and/or isolate such noise from reaching the pads of the memory device 10. The databus 46, the IO interface 16, and/or the command interface 14 may include such NFs 48. The NFs 48 may include resistance-capacitance (RC) filters in the databus or other buses/paths, large capacitors in the array, and/or other circuitry. However, at least some noise may reach the pads of the memory device 10.

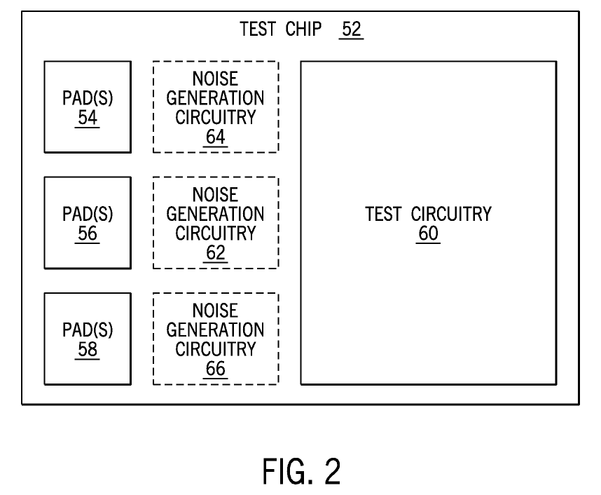

In practice, at least some aspects of the memory device 10 may demand testing during before, during, and/or after manufacture. To aid in testing specific features, such as IO circuitry, a simplified test die or chip may be produced to emulate behavior of the memory device without all features (e.g., memory banks 12 and/or bank controls 22). FIG. 2 is a block diagram of a test chip 52 that includes pad(s) 54, 56, and 58. Each of the pad(s) 54, 56, and/or 58 may include individual pads or groups of pads. Furthermore, although only three pads are shown, any suitable number of pads may be included in the test chip 52.

The test chip 52 includes some test circuitry 60 that reproduces or emulates operations of the memory device 10. For instance, the test circuitry 60 may include IO circuitry that is exactly like or similar to IO circuitry of the memory device 10. However, the test chip 52 (and the test circuitry 60) may omit the memory banks 12 and/or bank controls 22. Thus, the test chip 52 may lack the same array-based noise that its pad(s) 54, 56, and/or 58 may experience.

To more closely align to operation of the memory device 10, the test chip 52 may include noise generation circuitry 62 that is used to generate noise on power rails similar to the noise generated in the memory array. For instance, the noise generation circuitry 62 may be located at or near respective pad(s), such as pad(s) 56. In some embodiments, a single noise generation circuitry 62 may be used to generate noise for up to all pads of the test chip 52. Additionally or alternatively, other copies of the noise generation circuitry 62 may be located near other respective pad(s). For instance, in such embodiments, the test chip 52 may include noise generation circuitry 64 located nearer to the pad(s) 54 than to other pads, the noise generation circuitry 62 located nearer to the pad(s) 56 than to other pads, and noise generation circuitry 66 located nearer to the pad(s) 58 than to other pads. In other words, each pad or group of pads may have its own noise generation circuitry that is closer than other noise generations circuitries. The noise generations circuitries 62, 64, and/or 66 may be connected to power rails of the test chip 52 using wired connections and/or may couple to the power rails using capacitive coupling.

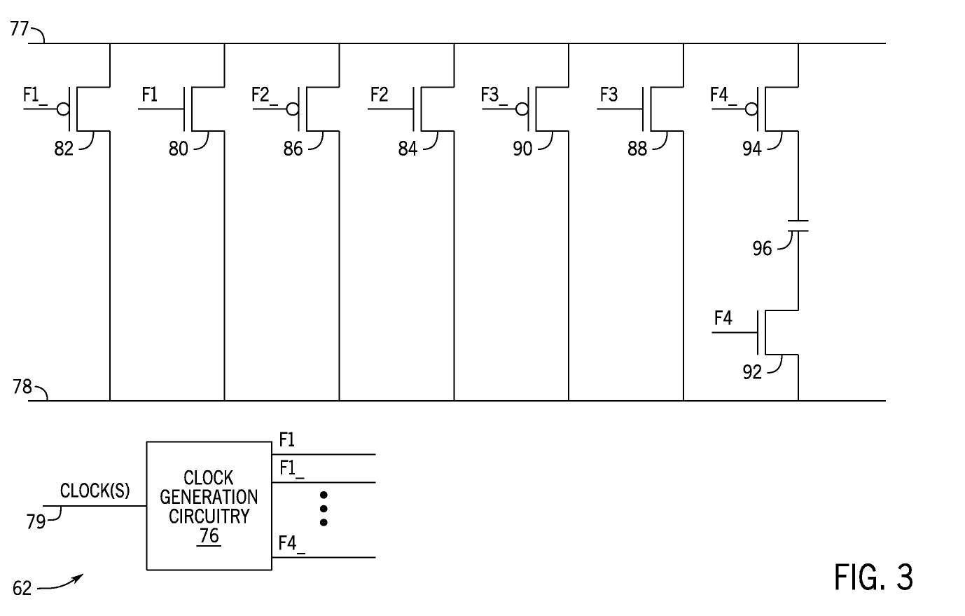

FIG. 3 is a schematic diagram of an embodiment of the noise generation circuitry 62. The noise generation circuitries 64 and 66 may be similarly constructed. The noise generation circuitry 62 may include a clock generation circuitry 76 that generates multiple frequency signals (F1, F2, F3, F4, etc.). For instance, the clock generation circuitry may use frequency multiplication, frequency division, phase-locked loops (PLLs) and/or other frequency synthesization techniques. In some implementations, the clock generation circuitry 76 may be separate from the noise generation circuitry 62. The individual frequencies may be those that most closely match frequency components of a current profile measured at the pads of the memory device 10 reflecting memory array noise. The current profile may be analyzed using frequency analysis (e.g., Fourier analysis) to determine frequency components. The frequencies that most heavily contribute to the current profile, as determined using Fourier analysis, may be generated in the clock generation circuitry 76 to short power rails 77 (e.g., VCC) and 78 (e.g., VSS) through respective transistors at rates that emulate/mimic the array noise seen at the pads of the memory device 10. The clock generation circuitry 76 may receive indications of which frequencies to generate by a host device 47, another processor, and/or a controller of the test chip 52.

The clock generation circuitry 76 of the noise generation circuitry 62 may utilize one or more clocks 79. For instance, the clock(s) 79 may include and/or be based on Clk_t or Clk_c received at the test chip 52 (e.g., from the host device 47) like the memory device 10 may be driven by the host device 47. The clock generation circuitry 76 may generate multiple different frequencies (e.g., F1, F2, F3, F4, etc.) from a single reference signal (e.g., Clk_t) of the clock(s) 79. Likewise, the clock generation circuitry 76 may generate multiple complementary signals (e.g., F1_, F2_, F3_, F4_, etc.) from the single reference signal and/or from a complementary reference signal (e.g., Clk_c) of the clock(s) 79. Furthermore, as discussed below, the clock generation circuitry 76 may generate at least some complementary signal (e.g., F1 and F1_, F2 and F2_, F3 and F3_, F4 and F4_, etc.) with at least some phase difference between the two signals. In other words, the signals may have the same frequency, but one of the signals may be delayed in the clock generation circuitry 76 to enable any dips in the voltage rails 77 and 78 to be offset from each other by the amount of delay.

As illustrated, the noise generation circuitry 62 includes a transistor 80 that receives a first true signal F1 with a first generated frequency at its gate terminal to short the voltage rails 77 and 78 together with each pulse (e.g., logic high) of F1. For instance, the transistor 80 may be an n-type metal oxide semiconductor (NMOS) transistor that shorts the voltage rails 77 and 78 with each pulse of F1.

In some implementations where the clock generation circuitry 76 generates complementary signals to perform differential signaling, the noise generation circuitry 62 may include a transistor 82 that receives a first bar signal F1_ that has the first generated frequency but is complementary to F1. The transistor 82 receives F1_ at its gate terminal to short the voltage rails 77 and 78 together with each pulse (e.g., logic low) of F1_. For instance, the transistor 82 may be a p-type metal oxide semiconductor (PMOS) transistor that shorts the voltage rails 77 and 78 with each pulse of F1_.

The amount of change in the voltage rails 77 and 78 due to the signals F1 and F1_ may be controlled by the width of the transistors 80 and 82. Larger widths for the transistors 80 and/or 82 result in larger changes to the voltage rails 77 and 78.

As illustrated, the noise generation circuitry 62 includes a transistor 84 that receives a second true signal F2 with a second generated frequency at its gate terminal to short the voltage rails 77 and 78 together with each pulse (e.g., logic high) of F2. For instance, the transistor 84 may be an NMOS transistor that shorts the voltage rails 77 and 78 with each pulse of F2.

In some implementations where the clock generation circuitry 76 generates complementary signals to perform differential signaling, the noise generation circuitry 62 may include a transistor 86 that receives a second bar signal F2_ that has the second generated frequency but is complementary to F2. The transistor 86 receives F2_ at its gate terminal to short the voltage rails 77 and 78 together with each pulse (e.g., logic low) of F2_. For instance, the transistor 86 may be a PMOS transistor that shorts the voltage rails 77 and 78 with each pulse of F2_.

As illustrated, the noise generation circuitry 62 includes a transistor 88 that receives a third true signal F3 with a third generated frequency at its gate terminal to short the voltage rails 77 and 78 together with each pulse (e.g., logic high) of F3. For instance, the transistor 88 may be an NMOS transistor that shorts the voltage rails 77 and 78 with each pulse of F3.

In some implementations where the clock generation circuitry 76 generates complementary signals to perform differential signaling, the noise generation circuitry 62 may include a transistor 90 that receives a third bar signal F3_ that has the third generated frequency but is complementary to F3. The transistor 90 receives F3_ at its gate terminal to short the voltage rails 77 and 78 together with each pulse (e.g., logic low) of F3_. For instance, the transistor 90 may be a PMOS transistor that shorts the voltage rails 77 and 78 with each pulse of F3_.

As illustrated, the noise generation circuitry 62 includes a transistor 92 that receives a fourth true signal F4 with a fourth generated frequency at its gate terminal to short the voltage rail 78 across the transistor 92 with each pulse (e.g., logic high) of F4. For instance, the transistor 92 may be an NMOS transistor that shorts the voltage rail 78 across the transistor 92 with each pulse of F4.

The noise generation circuitry 62 may include a transistor 94 that receives a fourth bar signal F4_ that has the fourth generated frequency but is out of phase (more or less than 180° as the other complementary signals) with F4. The transistor 94 receives F4_ at its gate terminal to short the voltage rail 77 across the transistor 94 with each pulse (e.g., logic low) of F4_. For instance, the transistor 94 may be a PMOS transistor that shorts the voltage rail 77 across the transistor 94 with each pulse of F2_.

Since the transistors 92 and 94 are connected in series between the voltage rails 77 and 78 and the signals F4 and F4_ are phase shifted relative to each other, during at least part of the shorting across the respective transistors 92 and 94, there is no short between the voltage rails 77 and 78. Thus, to pull voltage from the voltage rail 77 and/or to add voltage to the voltage rail 78 as noise, a capacitor 96 may be connected between the transistors 92 and 94 to enable the voltage rail 77 to charge the capacitor 96 when F4_ is asserted and F4 is not asserted causing noise on the voltage rail 77. Likewise, when F4 is asserted and F4_ is not asserted, the capacitor 96 may dissipate voltage to the voltage rail 78 as noise. Accordingly, the noise asserted on the voltage rails 77 and 78 via the transistors 94 and 92 may be phase shifted relative to each other.

The amount of change in the voltage rails 77 and 78 due to the signals may be controlled by the width of the respective transistors. As previously noted, larger widths for the transistors result in larger changes to the voltage rails 77 and 78 for the respective frequency signals. Moreover, different transistor widths may be used for different signals. Thus, when the current profile is Fourier analyzed for the frequency components, the larger frequency components may be assigned to signals (e.g., F1 and F1_) that drive corresponding larger transistors (e.g., transistor 80 and 82) compared to other transistors (e.g., band 90).

Furthermore, although only 1 differential pair (e.g., transistors 92 and 94) has a phase shift that impacts to the voltage rails 77 and 78, any number of signal pairs may be configured to apply phase shifts by connecting transistors in series between the voltage rails 77 and 78 with a capacitor between them. For instance, in some implementations, all transistors may be connected parallel with no phase shifting for a differential pair (e.g., F4 and F4_). Alternatively, all or just some of NMOS and PMOS pairs may be connected in series to enable phase shifting for each differential signal pair.

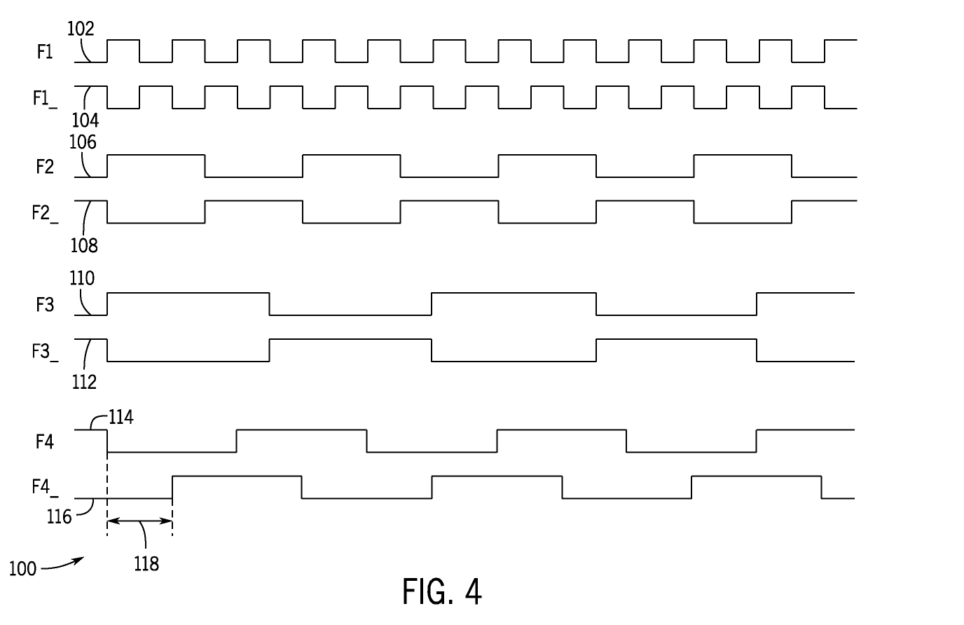

FIG. 4 is a timing diagram 100 of signals F1, F1_, F2, F2_, F3, F3_, F4, and F4_ that may be used in the noise generation circuitry 62 of FIG. 3. As illustrated, each pair (F1 and F1_, F2 and F2_, F3 and F3_, and F4 and F4_) may each have a different frequency that matches the frequency component found in Fourier analysis of the current profile of the memory device. As previously noted, each signal is matched to a transistor width of its transistor(s) based on the contribution of the frequency component to the noise analyzed using Fourier transforms. In some embodiments, the widths are proportional to the contribution of the frequency component applied to the transistor, such that the highest contributing frequency component is applied to the widest transistor. The timing diagram 100 does not show which signals correspond to wider width-transistors, but the signals or signal pairs may each map to different width transistors. Additionally or alternatively, at least some of the transistors have the same width. Additionally or alternatively, at least some frequency components may be the same between different signals.

As illustrated, the signals F1 and F1_ are respectively represented using lines 102 and 104. Likewise, the signals F2 and F2_ are respectively represented using lines 106 and 108. Similarly, the signals F3 and F3_ are respectively represented using lines 110 and 112. Similarly, the signals F4 and F4_ are respectively represented using lines 114 and 116.

As illustrated in the timing diagram 100, the signals F1 and F1_ are complementary signals that are in phase with each other where the signal F1 is high when the signal F1_ is low and vice versa. Thus, the signals F1 and F1_ may have the same frequency as each other.

Moreover, as illustrated in the timing diagram 100, the signals F2 and F2_ are complementary signals that are in phase with each other where the signal F2 is high when the signal F2_ is low and vice versa. Thus, the signals F2 and F2_ may have the same frequency as each other but a frequency lower than that of F1 and F1_. For instance, in the illustrated embodiment in the timing diagram 100, the frequency of the signals F1 and F1_ is 3X that of the frequency of the signals F2 and F2_. However, this frequency difference may be different in different embodiments.

Furthermore, the signals F3 and F3_ are complementary signals that are in phase with each other where the signal F3 is high when the signal F3_ is low and vice versa. Thus, the signals F3 and F3_ may have the same frequency as each other but a frequency lower than that of F2 and F2_ and that of F1 and F1_. For instance, in the illustrated embodiment in the timing diagram 100, the frequency of the signals F1 and F1_ is 5X that of the frequency of the signals F3 and F3_.

As may be understood, complementary signals are two signals that are 180° out of phase with each other. The signals F4 and F4_ would be complementary except that the signals are phase shifted by a delay 118 to change the phase difference between F4 and F4_. As previously noted, this delay 118 allows the voltage rails 77 and 78 to dip independently and/or at different times to enable the test chip 52 to more closely model monitored noise in the memory device.

Although the foregoing relates to frequency ratios between different signals (e.g., F1 and F2 or F2 and F3), other ratios may be deployed in different embodiments without changing the scope of the disclosure.

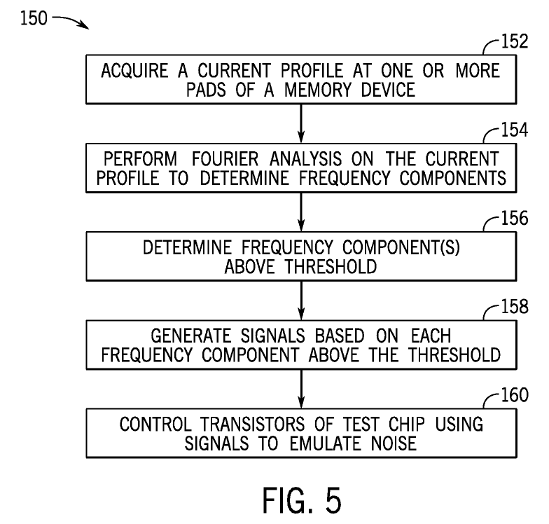

FIG. 5 is a flow diagram illustrating a process 150 for designing and driving the noise generation circuitry of FIG. 3 in the test chip of FIG. 2, according to an embodiment of the present disclosure. The process 150 begins with acquiring a current profile at one or more pads of the memory device 10 (block 152). For instance, the host device 47 may monitor the current profile of the memory device 10 using monitoring of one or more electrical parameters (e.g., voltage) at one or more pads of the memory device 10. Additionally or alternatively, the current profile of the memory device 10 may be received at the host device 47 from a user and/or retrieved from memory. The current profile may be linked to a specific mode and/or mode registers of the memory device 10.

The host device 47 then performs a Fourier analysis on the current profile to determine frequency components at pads of the memory device (block 154). For instance, the frequency components may be determined using a Fourier transform applied to a monitored signal output from the pads of the memory device 10 during operation. The frequency components may at least partially correspond to noise generated by a memory array of the memory device 10.

The host device 47 determines which frequency component(s) are above a threshold (block 156). For instance, the threshold may be proportional to (e.g., 10 %, 20 %, 30 %, and the like) a maximum amplitude of the frequency components. In other words, any frequency components that are at least the threshold (e.g., 0.30, etc.) proportion to the greatest frequency component contributor to the noise along with the greatest frequency component contributor are determined to be above the threshold. This threshold may be static or may be dynamic. For instance, there may be a limited number of available transistors for the frequency components. In such embodiments, the number of frequency components deemed above the threshold are the top N frequency component contributors to the noise where N is the number of transistor pairs (e.g., NMOS and PMOS pairs) available in the noise generation circuitry.

The noise generation circuitry 62 generates signals based on each frequency component above the threshold (block 158). For instance, the host device 47, a controller of the test die 52 (e.g., in the test circuitry 60), and/or another host device may instruct/program the test die 52 to control which frequencies are to be generated in the clock generation circuitry 76. Furthermore, the host device 47, the controller, and/or another host device may instruct which frequency signals are to be applied to which transistors of the noise generation circuitry 62. For instance, noise tuning parameters may be stored in test die 52 and/or a host device (e.g., host device 47) at a different time than the current profile is captured.

The noise generation circuitry 62 then uses the generated signals to control transistors of the test chip 52 to emulate noise generated by the memory device 10 (block 160). As previously noted, this control may include phase shifting at least one signal along with charging and discharging a capacitor 96 to ensure that the voltage rails 77 and 78 may dip independently and/or at different times. By emulating the noise generated in the memory device 10, the test chip 52 may enable a more realistic test scenario without the extra cost complexity and/or costs of actually including a memory array and associated bank control in the test chip 52.

Moreover, sometimes stacks of memory die having memory banks may be stacked die that use powerbond wire or other wire bonding technology to share wires between dies of the stack. Testing may be performed similarly with stacked test dies 52. Additionally or alternatively, in some testing scenarios, the noise generated by a respective test chip may be tuned according to particular locations within the stack. In other words, the current profile may specify a location in the stack with corresponding noise modeling output from the test chip 52.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A semiconductor device, comprising:
a test chip comprising:
test circuitry that matches circuitry of a memory device to enable testing on an aspect of the memory device using the test chip;
one or more voltage rails configured to propagate a voltage through the test chip;
one or more pads configured to provide inputs to and outputs from the test chip; and
one or more noise generation circuitries configured to emulate noise at memory pads of the memory device during operation of the memory device, wherein the one or more noise generation circuitries each comprise:
clock generation circuitry configured to generate one or more signals each having a frequency of one or more frequency components of the noise at the memory pads of the memory device; and
one or more transistors each configured to receive at least one of the one or more signals at a respective gate terminal of the respective one or more transistors to short at least one of the one or more voltage rails based on the at least one of the one or more signals.

2. The semiconductor device of claim 1, wherein the test chip does not comprise an array of memory elements or an associated bank control relying on the one or more noise generation circuitries to emulate noise as if generated from the array that is omitted from the test chip.

3. The semiconductor device of claim 1, wherein the one or more signals comprises differential signaling with a first signal of the one or more signals and a second signal of the one or more signals having a same frequency but out of phase with each other.

4. The semiconductor device of claim 3, wherein the first and second signals are 180° out of phase with each other.

5. The semiconductor device of claim 4, wherein the one or more transistors comprise:
an n-type metal oxide semiconductor transistor coupled between two voltage rails of the one or more voltage rails and configured to receive the first signal at a gate of the n-type metal oxide transistor; and
a p-type metal oxide semiconductor transistor coupled between the two voltage rails and configured to receive the second signal at a gate of the p-type metal oxide transistor.

6. The semiconductor device of claim 3, wherein the first and second signals are phase shifted relative to each other with a phase difference other than 180°.

7. The semiconductor device of claim 6, wherein the one or more noise generation circuitries comprises a capacitor, and the one or more transistors comprises:
a first transistor coupled between a first voltage rail of the one or more voltage rails and the capacitor and configured to receive the first signal at its gate terminal; and
a second transistor coupled between a second voltage rail of the one or more voltage rails and the capacitor and configured to receive the second signal at its gate terminal.

8. The semiconductor device of claim 7, wherein the capacitor and the phase difference enable the one or more noise generation circuitries to generate independent dips as noise on the first and second voltage rails.

9. The semiconductor device of claim 7, wherein the first transistor comprises a p-type metal oxide semiconductor transistor that is configured to charge the capacitor based on assertion of the first signal, and the second transistor comprises an n-type metal oxide semiconductor transistor that is configured to discharge the capacitor based on assertion of the second signal.

10. The semiconductor device of claim 1, wherein each of the one or more signals are assigned to a corresponding one or more transistors in a descending order where signals with frequencies that correspond to greater contribution of the noise are assigned to wider transistors than frequencies that correspond to lesser contribution to the noise.

11. The semiconductor device of claim 1, wherein the test circuitry comprises input-output (IO) circuitry that emulates IO circuitry of the memory device while the one or more noise generation circuitries mimics noise generated by a memory array of the memory device.

12. The semiconductor device of claim 1, wherein the one or more signals comprises a plurality of frequency signal pairs wherein each of the one or more signals in each of the plurality of frequency signal pairs has a same frequency as a corresponding one or more signals in the respective frequency signal pair, and each of the plurality of frequency signal pairs has a different frequency than other frequency signal pairs of the plurality of frequency signal pairs.

13. The semiconductor device of claim 1, wherein the emulated noise is tuned to a stack location of a potential memory die to be tested using the test chip.

14. A method, comprising:
acquiring, at a processor, a current profile at one or more pads of a memory device;
performing, by the processor, frequency analysis on the current profile to determine frequency components of noise at the one or more pads;
determining, by the processor, contributions of frequency components above a threshold;
instructing, by the processor, noise generation circuitry of a test chip to generate signals based on each of the frequency components above the threshold;
generating, by clock generation circuitry of the noise generation circuitry, the signals based on each of the frequency components above the threshold; and
controlling transistors of the noise generation circuitry using the signals to generate emulated noise to mimic the noise of the memory device.

15. The method of claim 14, wherein the noise is based at least in part on array noise generated by a memory array of the memory device, and generating the emulated noise comprises emulating the array noise propagated to the one or more pads in the noise.

16. The method of claim 15, wherein emulating the array noise comprises generating noise without a memory array in the test chip.

17. The method of claim 15, wherein emulating the array noise comprises shorting voltage rails of the test chip together using the signals by applying the signals to transistors of the noise generation circuitry.

18. The method of claim 15, wherein the signals are paired into pairs that have a same frequency, and at least some of the pairs are out of phase with each other.

19. A system, comprising:
a processor configured to execute instructions, that when executed, are configured to cause the processor to:
acquire a current profile at one or more pads of a memory device;
perform frequency analysis on the current profile to determine frequency components of array noise at the one or more pads;
determine contributions of frequency components above a threshold; and
send instructions to generate signals based on each of the frequency components above the threshold;
a test chip coupled to the processor and comprising:
clock generation circuitry configured to receive the instructions and to generate the signals based on the instructions; and
noise generation circuitry configured to switch a plurality of transistors to short voltage rails together to generate emulated noise to mimic memory array noise of the memory device.

20. The system of claim 19, wherein the test chip does not include a memory array.
